(19) United States
(12) Patent Application Publication
(10) Pub. No.: US 2023/0357914 A1
(43) Pub. Date: Nov. 9, 2023

(54) MASK PLATE ASSEMBLY AND METHOD FOR MANUFACTURING SAME

(71) Applicants: Chengdu BOE Optoelectronics Technology Co., Ltd., Chengdu, Sichuan (CN); BOE Technology Group Co., Ltd., Beijing (CN)

(72) Inventors: Wenxu LV, Beijing (CN); Qingfeng WU, Beijing (CN); Yongmao WANG, Beijing (CN); Wenchang ZHANG, Beijing (CN)

(21) Appl. No.: 18/026,293

(22) PCT Filed: Jan. 15, 2021
(86) PCT No.: PCT/CN2021/072207

§ 371 Date: Mar. 14, 2023

(51) Int. Cl. C23C 14/24; C23C 14/04

(52) U.S. Cl. CPC C23C 14/042; C23C 14/24

(57) ABSTRACT

Provided is a mask plate assembly. The mask plate assembly includes: a frame, wherein an opening portion is defined in a center portion of the frame; a shielding strip, wherein the shielding strip is disposed on the opening portion, and two ends of the shielding strip are fixed on the frame; and a mask plate, wherein the mask plate is fixed on the frame, and an evaporation hold and an elongated hole are defined in the mask plate, wherein the evaporation hole is opposite to the opening portion, and the elongated hole is opposite to the shielding strip to shield the elongated hole by the shielding strip.

### CROSS-REFERENCE TO RELATED APPLICATIONS

This application is a U.S. national stage of international application No. PCT/CN2021/072207, filed on Jan. 15, 2021, the disclosure of which is incorporated herein by reference in its entirety.

### TECHNICAL FIELD

The present disclosure relates to the field of evaporation technologies, and in particular, relates to a mask plate assembly and a method for manufacturing the same.

### BACKGROUND OF THE INVENTION

In some practices, due to different arrangements of products, mask plates welded on a frame are in different shapes.

### SUMMARY OF THE INVENTION

Embodiments of the present disclosure aim to solve at least one of problems in some practices. With this purpose, some embodiments of the present disclosure provide a mask plate assembly.

Some embodiments of the present disclosure further provide a method for manufacturing the mask plate assembly.

According to the mask plate assembly in some embodiments of the present disclosure, the mask plate assembly includes: a frame, wherein an opening portion is defined in a center portion of the frame; a shielding strip, wherein the shielding strip is disposed on the opening portion, and two ends of the shielding strip are fixed on the frame; and a mask plate, wherein the mask plate is fixed on the frame, and an evaporation hold and an elongated hole are defined in the mask plate, wherein the evaporation hole is opposite to the opening portion, and the elongated hole is opposite to the shielding strip to shield the elongated hole by the shielding strip.

In some embodiments of the present disclosure, the elongated hole includes a first elongated hole, and an evaporation region and a connection region are defined in the mask plate, wherein the connection region is outside the evaporation region, the evaporation hole is within the evaporation region, the connection region is connected to the frame, and a transition region is present between the connection region and the evaporation region, wherein the first elongated hole is defined in the transition region.

In some embodiments of the present disclosure, a plurality of first elongated holes are defined, and the plurality of first elongated holes are spaced apart in a circumferential direction of the mask plate.

In some embodiments of the present disclosure, an observation hole is defined in the mask plate, wherein the observation hole is indented inwards from an edge of the mask plate, the first elongated hole is defined in a side, proximal to a center of the mask plate, of the observation hole, and at least one of the first elongated holes is connected to the observation hole.

In some embodiments of the present disclosure, a plurality of evaporation holes are defined, wherein the plurality of evaporation holes are arranged in multiple rows and multiple columns, and the elongated hole includes a second elongated hole, wherein the second elongated hole is disposed between two adjacent rows of evaporation holes and/or two adjacent columns of evaporation holes.

In some embodiments of the present disclosure, the mask plate is provided with a plurality of first entity regions spaced apart in a first direction and a plurality of second entity regions spaced apart in a second direction, wherein the first direction is perpendicular to the second direction, widths of the plurality of first entity regions are equal, and/or widths of the plurality of second entity regions are equal.

In some embodiments of the present disclosure, the shielding strip is disposed between the frame and the mask plate.

In some embodiments of the present disclosure, a recess is defined in the frame, wherein the two ends of the shielding strip are fixed in the recess.

In some embodiments of the present disclosure, a thickness of the shielding strip is less than or equal to a depth of the recess.

In some embodiments of the present disclosure, the frame is a metal member, the shielding strip is a stainless steel member, the mask plate is an invar alloy member, and the shielding strip and the mask plate are welded on the frame.

According to the method for manufacturing the mask plate assembly in some embodiments of the present disclosure, the mask plate assembly is the mask plate assembly according to above embodiments. The manufacturing method includes: providing a frame; fixing two ends of a shielding strip on the frame; and fixing a mask plate on the frame, and defining an elongated hole in the mask plate to be opposite to the shielding strip.

Additional aspects and technical effects of the present disclosure are shown in the following descriptions, some of which are obvious from the following descriptions, or understood by embodiments of the present disclosure.

### BRIEF DESCRIPTION OF DRAWINGS

Above and/or additional aspects and technical effects of the present disclosure are obvious and easily understood based on the descriptions of the embodiments in conjunction with the accompanying drawings.

FIG. 1 is a schematic diagram of a mask plate assembly according to some embodiments of the present disclosure;

FIG. 2 is a schematic diagram of a frame and a shielding strip according to some embodiments of the present disclosure;

FIG. 3 is a schematic diagram of a frame and a shielding strip according to some embodiments of the present disclosure;

FIG. 4 is a side view of the frame and the shielding strip shown in FIG. 3; and

FIG. 5 is a schematic diagram of a mask plate according to some embodiments of the present disclosure.

Reference numerals:
mask plate assembly: 100; frame: 1; recess: 11; opening portion: 12;
shielding strip: 2;
mask plate: 3; evaporation hole: 31; elongated hole: 32; first elongated hole 32a; second elongated hole: 32b; observation hole: 33; first entity region: 34; and second entity region: 35.

### DETAILED DESCRIPTION OF THE INVENTION

The embodiments of the present disclosure are described hereinafter in detail, examples of which are illustrated in the accompanying drawings. Throughout the accompanying drawings, the same or similar reference numerals represent the same or similar components or components with the same or similar functions. The embodiments described below with reference to the accompanying drawings are exemplary, and are only intended to explain the present disclosure, rather than to limit the present disclosure.

In some practices, due to different arrangements of products, mask plates welded on a frame are in different shapes. However, in the case that an entity region of the mask plate is great, tension on the mask plate is great, such that an flexibility of a mask plate strip is poor. Thus, a force in evaporation process is uneven, an undesirable phenomenon, such as a mixed color effect at an edge, caused by fitting is present, and thus an evaporation effect is affected.

The mask plate assembly 100 is described hereinafter based on the embodiments of the present disclosure with reference to the accompanying drawings.

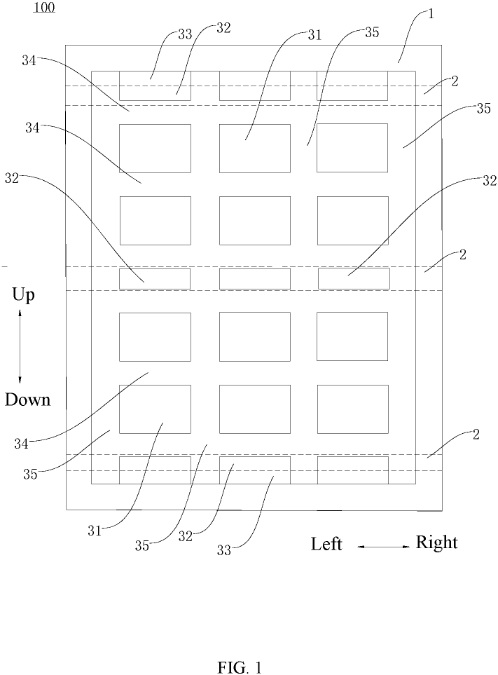

As shown in FIG. 1, the mask plate assembly 100 in the first aspect of the embodiments of the present disclosure includes a frame 1, a shielding strip 2, and a mask plate 3.

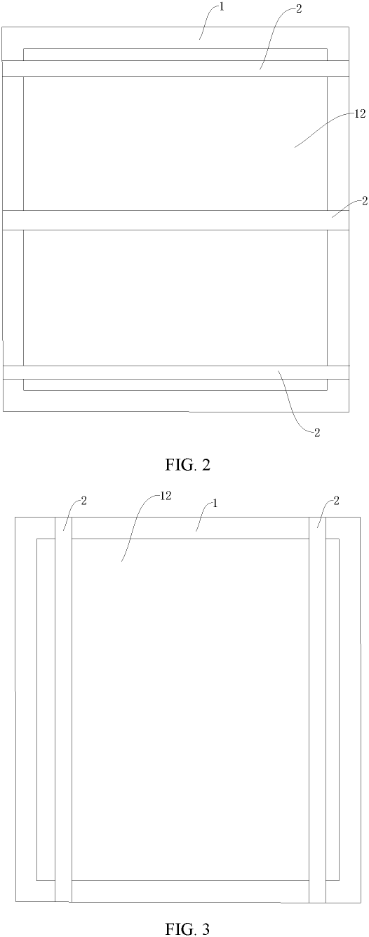

Referring to FIG. 2 and FIG. 3, the frame 1 is an annular structure, and an opening portion 12 is defined in a center portion of the frame 1. The shielding strip 2 is disposed on the opening portion 12, and two ends of the shielding strip 2 are fixed on the frame 1. The shielding strip 2 is in a strip, and the two ends of the shielding strip 2 in a length direction are fixed on the frame 1.

For example, a plane parallel to a plane of an end face of the frame 1 is defined as a reference face, and an orthogonal projection of the center portion of the shielding strip 2 on the reference face is within an orthogonal projection of the opening portion 12 on the reference face. The “center portion of the shielding strip 2” in the present disclosure should be understood broadly and is not in a strict sense, and positions between the two ends of the shielding strip 2 in the length direction are the “center portion of the shielding strip 2” in the present disclosure.

The mask plate 3 is fixed on the frame 1, and an evaporation hole 31 and an elongated hole 32 are defined in the mask plate 3. The evaporation hole 31 is opposite to the opening portion 12, and the elongated hole 32 is opposite to the shielding strip 2 to shield the elongated hole 32 by the shielding strip 2. An evaporation material is evaporated on a sample via an evaporation hole 31, and the elongated hole 32 is defined in an entity region, not provided with the evaporation hole 31, of the mask plate 3. As such, by defining the elongated hole 32 in the mask plate 3, and disposing the shielding strip 2 for shielding the elongated hole 32 on the frame 1, an area of entity region in the mask plate 3 is reduced, and tension on the mask plate 3 is reduced, such that an flexibility of the mask plate 3 is great. Furthermore, the force in evaporation process is ensured to be even, and the fitness between the mask plate 3 and a member to be evaporated is improved, such that an mixed color effect at an edge is great, an evaporation effect is improved, and the elongated hole 32 is prevented from affecting evaporation patterns.

In some embodiments of the present disclosure, a size of an orthogonal projection of the shielding strip 2 on the reference face in a direction perpendicular to an extension direction of the shielding strip 2 is greater than or equal to a size of an orthogonal projection of the elongated hole 32 on the reference face. As such, the shielding strip 2 entirely covers the elongated hole 32, such that the evaporation material is avoided being evaporated on the member to be evaporated via the elongated hole 32.

It should be noted that in the evaporation process, the member to be evaporated is disposed on a side, facing away from the frame 1, of the mask plate 3, and a side, facing away from the mask plate 3, of the member to be evaporated is provided with a magnetic adsorption device. The mask plate 3 is adsorbed by the magnetic adsorption device, such that the mask plate 3 and the member to be evaporated are fitted closely. It is found by the inventors of the present disclosure that in the case that the area of the entity region of the mask plate 3 is great, the tension on the mask plate 3 is increased, such that the flexibility of the mask plate is poor. Furthermore, the magnetic adsorption device fails to absorb a position of great entity region in the mask plate 3, such that the close fitness between the mask plate 3 and the member to be evaporated is greatly affected, the force is uneven, the undesirable phenomenon, such as the mixed color effect at the edge, caused by fitting is present, and thus the evaporation effect is affected.

According to the mask plate assembly 100 in the embodiments of the present disclosure, by defining the elongated hole 32 in the mask plate 3, the area of the entity region in the mask plate 3 is reduced, and the tension on the mask plate 3 is reduced, such that the flexibility of the mask plate 3 is great. Furthermore, the force in evaporation process is ensured to be even, and the fitness between the mask plate 3 and the member to be evaporated is improved, such that the mixed color effect at the edge is great, and the evaporation effect and the product yield are improved. In this case, the shielding strip 2 for shielding the elongated hole 32 is disposed on the frame 1, and the elongated hole 32 is shielded by the shielding strip 2, such that the evaporation material is avoided being evaporated on the member to be evaporated via the elongated hole 32, the elongated hole 32 is prevented from affecting the evaporation patterns, the structure is simple, and the design is smart.

In some embodiments of the present disclosure, the elongated hole 32 includes a first elongated hole 32a, and an evaporation region and a connection region are defined in the mask plate 3. The connection region is outside the evaporation region, the evaporation hole 31 is within the evaporation region, the connection region is connected to the frame 1, and a transition region is present between the connection region and the evaporation region. The first elongated hole 32a is defined in the transition region.

In the present disclosure, the “connection region” refers to a region in which the mask plate 3 and the frame 1 are connected, and the “evaporation region” refers to a region defined by outer edges of a row of evaporation holes 31 on a position most proximal to the edge of the mask plate 3. The evaporation region is a square region, a circular region, and the like. The “transition region” is a region disposed between the connection region and the evaporation region, and is an annular region.

The direction “outside” in the present disclosure refers to a direction from the center of the mask plate 3 to the edge of the mask plate 3. In addition, in the description of the present disclosure, it should be noted that the orientation or position relations indicated via terms of “center,” “longitudinal,” “transverse,” “length,” “width,” “thickness,” “left,” “right,” “vertical,” “horizontal,” “inner,” “outer,” “clockwise,” “counterclockwise,” “circumferential,” and the like are orientation or the position relations based on the accompanying drawings. They are merely for the purpose of convenience of description of the present disclosure, but not to indicate or imply that the device or member require to be constructed and operated with the particular orientation, and thus they should not be construed as limitations on the present disclosure.

Referring to FIG. 1, the connection region is connected to the frame 1, and an entity region between one row or one column of the evaporation holes 31 proximal to the edge of the mask plate 3 and the connection region is the transition region. By defining the first elongated hole 32a in the transition region, the tension on the periphery of the evaporation region of the mask plate 3 is reduced, such that the flexibility of the periphery the mask plate 3 is great. Furthermore, the force in evaporation process is ensured to be even, and the fitness between the mask plate 3 and the member to be evaporated is improved, such that the mixed color effect at the edge is great, and the evaporation effect is improved.

In some embodiments of the present disclosure, a plurality of first elongated holes 32a are defined, and the plurality of first elongated holes 32a are spaced apart in a circumferential direction of the mask plate. In the description of the present disclosure, the term “a plurality of” refers to two or more.

It should be noted that the “circumferential direction of the mask plate” in the present disclosure refers to an extension direction of outer contour of the mask plate. In some embodiments of the present disclosure, a plurality of first elongated holes 32a are disposed on all edges proximal to the mask plate 3. In some embodiments of the present disclosure, a plurality of first elongated holes 32a are disposed on some edges proximal to the mask plate 3. For example, as shown in FIG. 1, a plurality of first elongated holes 32a are disposed on an upper edge and a lower edge proximal to the mask plate 3. In some embodiments of the present disclosure, a plurality of first elongated holes 32a are disposed on a left edge and a right edge proximal to the mask plate 3. Thus, in the stretching process, the force of the mask plate 3 is even, the force in evaporation process is ensured to be even, and the fitness between the mask plate 3 and the member to be evaporated is improved, such that the mixed color effect at the edge is great, and the product yield is improved.

In some embodiments of the present disclosure, an observation hole 33 is defined in the mask plate 3. The observation hole 33 is indented inwards from an edge of the mask plate 3, the first elongated hole 32a is disposed on a side, proximal to a center of the mask plate 3, of the observation hole 33, and at least one first elongated hole 32a is connected to the observation hole 33. The observation hole 33 is configured to observe and detect a thickness of the evaporation material on the member to be evaporated. As shown in FIG. 1, the observation hole 33 is formed by indenting inwards from both edges of the mask plate 3 in the first direction. A plurality of first observation holes 33 are defined, and the plurality of observation holes 33 are spaced apart in the circumferential direction of the mask plate 3. The first elongated hole 32a is disposed on a side, proximal to the evaporation region, of the observation hole 33. Some of the plurality of first elongated holes 32a are connected to the observation hole 33, or all of the plurality of first elongated holes 32a are connected to the observation hole 33. As such, by defining the first elongated hole 32a in the side, proximal to the evaporation region, of the observation hole 33, and connecting at least one first elongated hole 32a to the observation hole 33, the manufacturing process of the mask plate 3 is simplified, the manufacturing efficiency is improved, and the manufacturing cost is reduced.

In some embodiments of the present disclosure, a plurality of evaporation holes 31 are defined. The plurality of evaporation holes 31 are arranged in multiple rows and multiple columns, and the elongated hole 32 includes a second elongated hole 32b. The second elongated hole 32b is disposed between two adjacent rows of evaporation holes 31 and/or two adjacent columns of evaporation holes 31. Specifically, the plurality of evaporation holes 31 are arranged in multiple rows and multiple columns, for example, M rows and N columns. The second elongated hole 32b is disposed between two adjacent rows of evaporation holes 31, or between two adjacent columns of evaporation holes 31, or between two adjacent rows of evaporation holes 31 and two adjacent columns of evaporation holes 31. As such, the tension of the evaporation region of the mask plate 3 is reduced, such that the flexibility of the mask plate 3 is great. Furthermore, the force in evaporation process is ensured to be even, and the fitness between the mask plate 3 and the member to be evaporated is improved, such that the mixed color effect at the edge is great, and the evaporation effect is improved.

In some embodiments of the present disclosure, the mask plate 3 is provided with a plurality of first entity regions 34 spaced apart in a first direction and a plurality of second entity regions 35 spaced apart in a second direction. The first direction is perpendicular to the second direction, widths of the plurality of first entity regions 34 are equal, and/or widths of the plurality of second entity regions 35 are equal. That is, the widths of the plurality of first entity regions 34 are equal, or the widths of the plurality of second entity regions 35 are equal, or the widths of the plurality of first entity regions 34 are equal and the widths of the plurality of second entity regions 35 are equal.

It should be noted that the term “perpendicular to” in “the first direction is perpendicular to the second direction” should be understood broadly. For example, in the case that an included angle between the first direction and the second direction ranges from 80° to 100°, it can be understood that the first direction is perpendicular to the second direction.

For example, in some embodiments of the present disclosure, the first direction is a length direction of the frame 1 (for example, an up-down direction shown in FIG. 1), and the second direction is a width direction of the frame 1 (for example, a left-right direction shown in FIG. 1). In the case that the first entity region 34 is formed between two adjacent rows of evaporation holes 31, the width of the first entity region 34 is a distance between two adjacent rows of evaporation holes 31. In the case that the first entity region 34 is formed between adjacent evaporation hole 31 and elongated hole 32, the width of the first entity region 34 is a distance between the adjacent evaporation hole 31 and elongated hole 32. In the case that the second entity region 35 is formed between two adjacent columns of evaporation holes 31, the width of the second entity region 35 is a distance between two adjacent columns of evaporation holes 31. In the case that the second entity region 35 is formed between adjacent evaporation hole 31 and elongated hole 32, the width of the second entity region 35 is a distance between the adjacent evaporation hole 31 and elongated hole 32.

Thus, in the case that the widths of the plurality of first entity regions 34 are equal, and/or the widths of the plurality of second entity regions 35 are equal, the tension on the mask plate is even. Furthermore, the force in evaporation process is ensured to be even, and the fitness between the mask plate and the member to be evaporated is improved, such that the mixed color effect at the edge is great, and the evaporation effect and the product yield are improved.

In some embodiments of the present disclosure, the shielding strip 2 is disposed between the frame 1 and the mask plate 3. Specifically, the shielding strip 2 and the mask plate 3 are disposed on a same side of the frame 1, and the shielding strip 2 is disposed on the side, proximal to the frame 1, of the mask plate 3. As such, the elongated hole 32 is shielded by the shielding strip 2, and interference between the shielding strip 2 and other member in the evaporation process is avoided.

In some embodiments of the present disclosure, a recess 11 is defined in the frame 1, and the two ends of the shielding strip 2 are fixed in the recess 11. In some embodiments of the present disclosure, the recess 11 is indented inwards from a face in one side of the frame 1 to a face in the other side of the frame 1. As such, by defining the recess 11 in the frame 1, and fixing the two ends of the shielding strip 2 in the recess 11, a distance between the mask plate 3 and the frame 1 is reduced, and the evaporation effect is ensured.

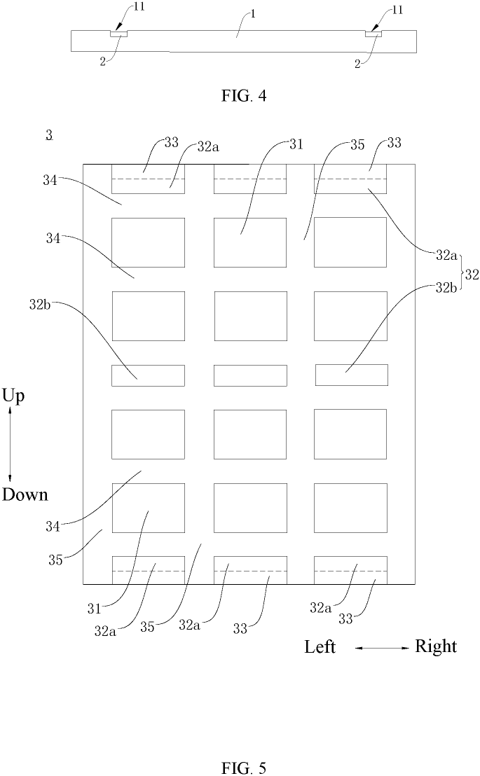

In some embodiments of the present disclosure, a thickness of the shielding strip 2 is less than or equal to a depth of the recess 11. For example, as shown in FIG. 4, the thickness of the shielding strip 2 is less than the depth of the recess 11. As such, the shielding strip 2 is prevented from protruding from a surface of the frame 1, such that the distance between the mask plate 3 and the frame 1 is reduced, and the evaporation effect is improved.

In some embodiments of the present disclosure, the frame 1 is a metal member, the shielding strip 2 is a stainless steel member, the mask plate 3 is an invar alloy member, and the shielding strip 2 and the mask plate 3 are welded on the frame 1. In some embodiments, the frame 1 is a stainless steel member. As such, it is convenient to welding the mask plate 3 and the shielding strip 2 on the frame 1, and the strength of the structure of the mask plate assembly 100 is improved.

According to the method for manufacturing the mask plate assembly 100 in some embodiments of the present disclosure, the mask plate assembly 100 is the mask plate assembly 100 according to above embodiments.

Specifically, the mask plate assembly 100 includes a frame 1, a shielding strip 2, and a mask plate 3. Referring to FIG. 2 and FIG. 3, the frame 1 is an annular structure, and an opening portion 12 is defined in a center portion of the frame 1. The shielding strip 2 is disposed on the opening portion 12, and two ends of the shielding strip 2 are fixed on the frame 1. The shielding strip 2 is in a strip. The mask plate 3 is fixed on the frame 1, and an evaporation hole 31 and an elongated hole 32 are defined in the mask plate 3. The evaporation hole 31 is opposite to the opening portion 12, and the elongated hole 32 is opposite to the shielding strip 2 to shield the elongated hole 32 by the shielding strip 2. An evaporation material is evaporated on a sample via an evaporation hole 31, and the elongated hole 32 is defined in an entity region, not provided with the evaporation hole 31, of the mask plate 3.

As such, by defining the elongated hole 32 in the mask plate 3, and disposing the shielding strip 2 for shielding the elongated hole 32 on the frame 1, an area of entity region on the mask plate 3 is reduced, and tension on the mask plate 3 is reduced, such that the flexibility of the mask plate 3 is great. Furthermore, the force in evaporation process is ensured to be even, and the fitness between the mask plate 3 and a member to be evaporated is improved, such that an mixed color effect at an edge is great, an evaporation effect is improved, and the elongated hole 32 is prevented from affecting evaporation patterns.

The method for manufacturing the mask plate assembly 100 includes:
providing a frame 1;
fixing two ends of a shielding strip 2 on the frame 1; and
fixing a mask plate 3 on the frame 1, and defining an elongated hole 32 in the mask plate 3 to be opposite to the shielding strip 2.

Specifically, the two ends of the shielding strip 2 is first welded on the frame 1, and the mask plate 3 is then welded on the frame 1. The shielding strip 2 and the mask plate 3 are disposed on a same side of the frame 1. The structure is simply, and the manufacturing process is convenient.

According to the method for manufacturing the mask plate assembly 100 in the embodiments of the present disclosure, by defining the elongated hole 32 in the mask plate 3, the area of the entity region on the mask plate 3 is reduced, and the tension on the mask plate 3 is reduced, such that the flexibility of the mask plate 3 is great. Furthermore, the force in evaporation process is ensured to be even, and the fitness between the mask plate 3 and the member to be evaporated is improved, such that the mixed color effect at the edge is great, and the evaporation effect and the product yield are improved. In this case, the shielding strip 2 for shielding the elongated hole 32 is disposed on the frame 1, and the elongated hole 32 is shielded by the shielding strip 2, such that the evaporation material is avoided being evaporated on the member to be evaporated via the elongated hole 32, the elongated hole 32 is prevented from affecting evaporation patterns, the structure is simple, and the design is smart.

In the descriptions of the present specification, the descriptions about reference terms such as “an embodiment,” “some embodiments,” “exemplary embodiments,” “examples,” “specific examples,” “some examples,” and the like mean that the specific features, structures, materials or characteristics described in combination with the embodiments are included in at least one embodiment of the present disclosure. In the present specification, the schematic descriptions of the above terms do not necessarily refer to a same embodiment or example. Furthermore, the specific features, structures, materials or characteristics as described can be integrated with any one or more embodiments or examples in a proper manner.

Although the embodiments of the present disclosure have been shown and described above, it can be understood by those skilled in the art that the above embodiments can be changed, modified, substituted and varied without departing from the principles and aims of the present disclosure, and the scope of the present disclosure is defined by claims and their equivalents.

1. A mask plate assembly, comprising:
a frame, wherein an opening portion is defined in a center portion of the frame;
a shielding strip, wherein the shielding strip is disposed on the opening portion, and two ends of the shielding strip are fixed on the frame; and
a mask plate, wherein the mask plate is fixed on the frame, and an evaporation hold and an elongated hole are defined in the mask plate, wherein the evaporation hole is opposite to the opening portion, and the elongated hole is opposite to the shielding strip to shield the elongated hole by the shielding strip.

2. The mask plate assembly according to claim 1, wherein the elongated hole comprises a first elongated hole, and an evaporation region and a connection region are defined in the mask plate, wherein the connection region is outside the evaporation region, the evaporation hole is within the evaporation region, the connection region is connected to the frame, and a transition region is present between the connection region and the evaporation region, wherein the first elongated hole is defined in the transition region.

3. The mask plate assembly according to claim 2, wherein a plurality of first elongated holes are defined, and the plurality of first elongated holes are spaced apart in a circumferential direction of the mask plate.

4. The mask plate assembly according to claim 2, wherein an observation hole is defined in the mask plate, wherein the observation hole is indented inwards from an edge of the mask plate, the first elongated hole is defined in a side, proximal to a center of the mask plate, of the observation hole, and at least one of the first elongated holes is connected to the observation hole.

5. The mask plate assembly according to claim 1, wherein a plurality of evaporation holes are defined, wherein the plurality of evaporation holes are arranged in multiple rows and multiple columns, and the elongated hole comprises a second elongated hole, wherein the second elongated hole is disposed between two adjacent rows of evaporation holes and two adjacent columns of evaporation holes.

6. The mask plate assembly according to claim 5, wherein the mask plate is provided with a plurality of first entity regions spaced apart in a first direction and a plurality of second entity regions spaced apart in a second direction, wherein the first direction is perpendicular to the second direction, widths of the plurality of first entity regions are equal, and widths of the plurality of second entity regions are equal.

7. The mask plate assembly according to claim 1, wherein the shielding strip is disposed between the frame and the mask plate.

8. The mask plate assembly according to claim 7, wherein a recess is defined in the frame, wherein the two ends of the shielding strip are fixed in the recess.

9. The mask plate assembly according to claim 8, wherein a thickness of the shielding strip is less than or equal to a depth of the recess .

10. The mask plate assembly according to claim 1, wherein the frame is a metal member, the shielding strip is a stainless steel member, the mask plate is an invar alloy member, and the shielding strip and the mask plate are welded on the frame.

11. A method for manufacturing a mask plate assembly, wherein the mask plate assembly comprises: a frame, wherein an opening portion is defined in a center portion of the frame; a shielding strip, wherein the shielding strip is disposed on the opening portion, and two ends of the shielding strip are fixed on the frame; and a mask plate, wherein the mask plate is fixed on the frame, and an evaporation hold and an elongated hole are defined in the mask plate, wherein the evaporation hole is opposite to the opening portion, and the elongated hole is opposite to the shielding strip to shield the elongated hole by the shielding strip; the method comprising:
providing the frame;
fixing the two ends of the shielding strip on the frame; and
fixing the mask plate on the frame, and defining the elongated hole in the mask plate to be opposite to the shielding strip.

12. The mask plate assembly according to claim 3, wherein an observation hole is defined in the mask plate, wherein the observation hole is indented inwards from an edge of the mask plate, the first elongated hole is defined in a side, proximal to a center of the mask plate, of the observation hole, and at least one of the first elongated holes is connected to the observation hole.

13. The mask plate assembly according to claim 1, wherein a plurality of evaporation holes are defined, wherein the plurality of evaporation holes are arranged in multiple rows and multiple columns, and the elongated hole comprises a second elongated hole, wherein the second elongated hole is disposed between two adjacent rows of evaporation holes or two adjacent columns of evaporation holes.

14. The mask plate assembly according to claim 5, wherein the mask plate is provided with a plurality of first entity regions spaced apart in a first direction and a plurality of second entity regions spaced apart in a second direction, wherein the first direction is perpendicular to the second direction, widths of the plurality of first entity regions are equal, or widths of the plurality of second entity regions are equal.

15. The mask plate assembly according to claim 2, wherein a plurality of evaporation holes are defined, wherein the plurality of evaporation holes are arranged in multiple rows and multiple columns, and the elongated hole comprises a second elongated hole, wherein the second elongated hole is disposed between two adjacent rows of evaporation holes and two adjacent columns of evaporation holes.

16. The mask plate assembly according to claim 3, wherein a plurality of evaporation holes are defined, wherein the plurality of evaporation holes are arranged in multiple rows and multiple columns, and the elongated hole comprises a second elongated hole, wherein the second elongated hole is disposed between two adjacent rows of evaporation holes and two adjacent columns of evaporation holes.

17. The mask plate assembly according to claim 4, wherein a plurality of evaporation holes are defined, wherein the plurality of evaporation holes are arranged in multiple rows and multiple columns, and the elongated hole comprises a second elongated hole, wherein the second elongated hole is disposed between two adjacent rows of evaporation holes and two adjacent columns of evaporation holes.

18. The mask plate assembly according to claim 2, wherein the shielding strip is disposed between the frame and the mask plate.

19. The mask plate assembly according to claim 3, wherein the shielding strip is disposed between the frame and the mask plate.

20. The mask plate assembly according to claim 4, wherein the shielding strip is disposed between the frame and the mask plate.
